(19) United States
(12) Patent Application Publication
(10) Pub. No.: US 2025/0308902 A1
(43) Pub. Date: Oct. 2, 2025

(54) USING LASER BASED SYSTEM FOR MEAN OF SHAPING OF UNSINGULATED & SINGULATED DIES BY SUBSTRATE LATTICE MANIPULATION

(71) Applicant: Tokyo Electron Limited, Tokyo (JP)

(72) Inventors: David CONKLIN, Saratoga Springs, NY (US); Anthony SCHEPIS, Averill Park, NY (US); Anton DEVILLIERS, Albany, NY (US)

(73) Assignee: Tokyo Electron Limited, Tokyo (JP)

(21) Appl. No.: 18/616,634

(22) Filed: Mar. 26, 2024

(51) Int. Cl. H01L 21/268; H01L 21/02; H01L 21/322

(52) U.S. Cl. CPC H01L 21/268; H01L 21/02532; H01L 21/322

(57) ABSTRACT

Aspects of the present disclosure provide a method for correcting distortion of a semiconductor substrate. For example, the method can include receiving a semiconductor substrate with distortion, measuring the semiconductor substrate to identify the distortion in a plurality of positions on the semiconductor substrate, and implanting into the semiconductor substrate a lattice configuration signature according to the identified distortion in the positions such that the identified distortion of the semiconductor substrate is corrected.

### FIELD OF THE PRESENT DISCLOSURE

The present disclosure relates generally to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, which has enabled the integration of heterogeneous functional circuits, such as logic and memory circuits, onto the same semiconductor substrate. However, 2D scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other as another means of further scaling of integrated circuits (ICs).

### SUMMARY

Aspects of the present disclosure provide a method for correcting distortion of a semiconductor substrate. For example, the method can include receiving a semiconductor substrate with distortion, measuring the semiconductor substrate to identify the distortion in a plurality of positions on the semiconductor substrate, and implanting into the semiconductor substrate a lattice configuration signature according to the identified distortion in the positions such that the identified distortion of the semiconductor substrate is corrected. In an embodiment, the positions can include XY positions. In another embodiment, the distortion in the XY positions can be identified by determining alignment mark registration, overlay mark registration and/or reference grid registration on the semiconductor substrate.

In an embodiment, implanting into the semiconductor substrate the lattice configuration signature can include focusing a light beam with an amount of energy in the positions on the semiconductor substrate. In another embodiment, focusing the light beam with the amount of energy can include focusing a laser light beam with an amount of laser energy. In yet another embodiment, the laser light beam can have power, pulse duration and pulse number that are adjusted according to the identified distortion in the positions. In an embodiment, the laser light beam can be tuned to a material and a lattice of the semiconductor substrate and an interface below the semiconductor substrate.

Aspects of the present disclosure also provide an apparatus for correcting distortion of a semiconductor substrate. For example, the apparatus can include a distortion measurement device configured to measure the semiconductor substrate to identify the distortion in a plurality of positions on the semiconductor substrate, a light source configured to implant a lattice configuration signature into the semiconductor substrate to distort the semiconductor substrate, and a controller coupled to the distortion measurement device and the light source, the controller configured to control the light source to implant the lattice configuration signature into the semiconductor substrate according to the identified distortion in the positions on the semiconductor substrate.

In an embodiment, the light source can be configured to implant into the semiconductor substrate the lattice configuration signature by focusing a light beam with an amount of energy in the positions on the semiconductor substrate. In another embodiment, the light source can be a laser light source that is configured to implant into the semiconductor substrate the lattice configuration signature by focusing a laser light beam with an amount of laser energy in the positions on the semiconductor substrate.

Note that this summary section does not specify every embodiment and/or incrementally novel aspect of the present disclosure or claimed disclosure. Instead, this summary only provides a preliminary discussion of different embodiments and corresponding points of novelty over conventional techniques. For additional details and/or possible perspectives of the present disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a simplified cross-sectional view of a semiconductor segment;

FIG. 2 shows a semiconductor substrate that includes two semiconductor segments fabricated in face-to-face 3D integration (3Di);

FIG. 3A shows a top view of a semiconductor substrate with no distortion;

FIGS. 3B-3D, 4A and 4B show top views of other semiconductor substrates with various types of distortion that can be corrected by the method; and

FIG. 5 is a flow chart illustrating an exemplary method of correcting distortion of a semiconductor substrate in accordance with some embodiments of the present disclosure; and

FIG. 6 is a functional block diagram of an exemplary apparatus for correcting distortion of a semiconductor substrate in accordance with some embodiments of the present disclosure.

### DETAILED DESCRIPTION

The word “exemplary” is used herein to mean, “serving as an example, instance or illustration.” Any embodiment of construction, process, design, technique, etc., designated herein as exemplary is not necessarily to be construed as preferred or advantageous over other such embodiments. Particular quality or fitness of the examples indicated herein as exemplary is neither intended nor should be inferred.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus (or device) in use or operation in addition to the orientation depicted in the figures. The apparatus (or device) may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of the present disclosure, it is intended that each of the concepts can be executed independently of each other or in combination with each other. Accordingly, the present disclosure can be embodied and viewed in many different ways.

As noted in the Background, semiconductor device fabricators have expressed a desire for 3D semiconductor devices in which transistors are stacked on top of each other as another means of scaling ICs, in addition to conventional 2D scaling. A 3D integration (3Di), i.e., the vertical stacking of semiconductor devices, aims to overcome 2D scaling limitations by increasing transistor density in volume rather than area. Although device stacking has been successfully demonstrated and implemented by the flash memory industry with the adoption of 3D NAND, application to random logic designs is substantially more difficult. 3D integration for logic chips such as central processing units (CPUs), graphics processing units (GPUs), field programmable gate arrays (FPGAs) and system on a chip (SoC) is being pursued primarily by two approaches: one approach is heterogeneous stacking, and the other approach is more of a homogeneous stacking.

Heterogeneous stacking uses wafer/chip (or die) stacking and through silicon via (TSV) technology, as disclosed in Process Integration Aspects enabling 3D sequential stacked planar and FINfet Technology, Anne VanDooren, IMEC PTW Spring 2018. For example, in this 3D integration approach two chips can be optimized in design and manufacturing for different specific tasks, e.g., one containing chemical and biological sensors, the other including nano-devices and micro-electromechanical system (MEMS) devices, and TSVs can be used to integrate these two different functional chips to build a stacked SoC. Details of heterogeneous integration approaches are provided in the Heterogeneous Integration Roadmap, 2019 edition published October 2019 at http://eps.ieee.org/hir.

Homogeneous stacking uses a wafer bonding process to overcome density loss associated with micron-sized TSVs that are used in heterogeneous stacking. For example, a base wafer can be processed to form devices such as n-type metal oxide semiconductors (nMOSs) and p-type MOSs (pMOSs), and several layers of metallization/wiring, and then a thinned silicon-on-insulator (SOI) layer can be positioned on top of the base wafer and bonded thereto by way of an oxide-oxide bond to form a completed structure.

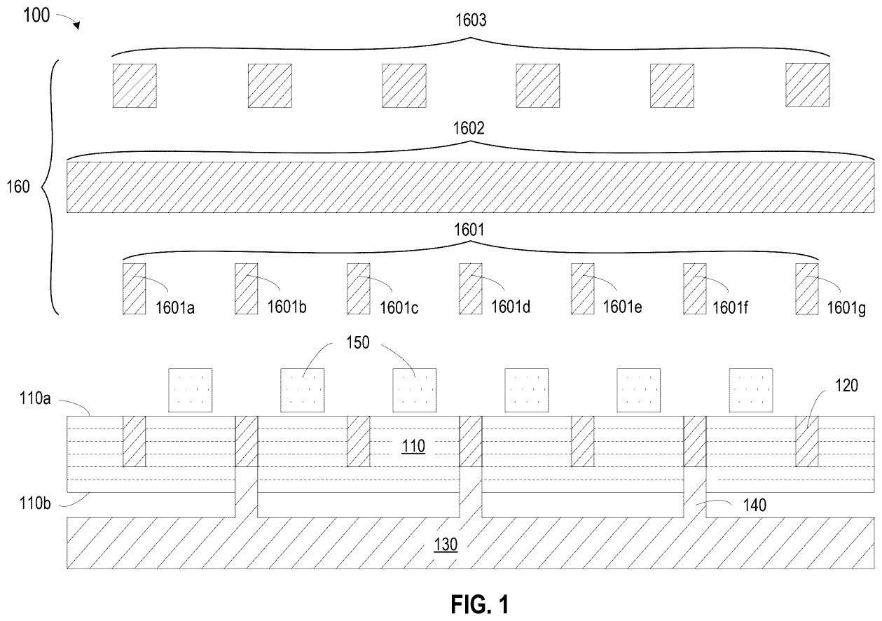

FIG. 1 shows a simplified cross-sectional view of a semiconductor segment 100. A substrate (or a wafer) 110, e.g., a silicon or SiGe substrate, can be provided. A tier of semiconductor devices (or a semiconductor device tier) 150 can be disposed on a front side 110a of the substrate 110. For example, the tier of semiconductor devices 150 can include one or more semiconductor devices, such as field effect transistors (FETs), that form a functional circuit, such as a logic circuit or a memory circuit. Further, these FETs can be n-type or p-type FETs that are arranged along the front side 110a or stacked vertically over one another along the thickness direction of the substrate 110.

One or more power rails 120 can be buried in the substrate 110 and electrically connect the tier of semiconductor devices 150 to a power delivery network (PDN) 130 by way of TSVs (e.g., nano-scale) 140 to provide low voltage (Vss) and high voltage (VDD) power delivery, for example, from the PDN 130 to the tier of semiconductor devices 150. The PDN 130 can be formed on a back side 110b of the substrate 110.

A signal wiring structure (or a wiring tier) 160 can be disposed over the tier of semiconductor devices 150 and used to electrically connect the tier of semiconductor devices 150 to, for example, another tier of semiconductor devices (not shown) disposed over the wiring tier 160. The wiring tier 160 can include one or more wiring layers (or wiring levels), with each wiring layer including one or more wiring tracks that extend in a direction along the front side 110a of the substrate 110. Generally, wiring tracks in one wiring layer will run in a direction perpendicular to the direction of wiring tracks in an adjacent wiring layer. For example, the wiring tier 160 can include a plurality of wiring layers, e.g., three wiring layers 1601, 1602 and 1603, and the wiring layer 1601 can include a plurality of wiring tracks, e.g., seven wiring tracks 1601a to 1601g, that extend in a direction (e.g., perpendicular to the plane of the drawing page) perpendicular to the direction of the wiring tracks in the wiring layer 1602 along the front side 110a of the substrate 110.

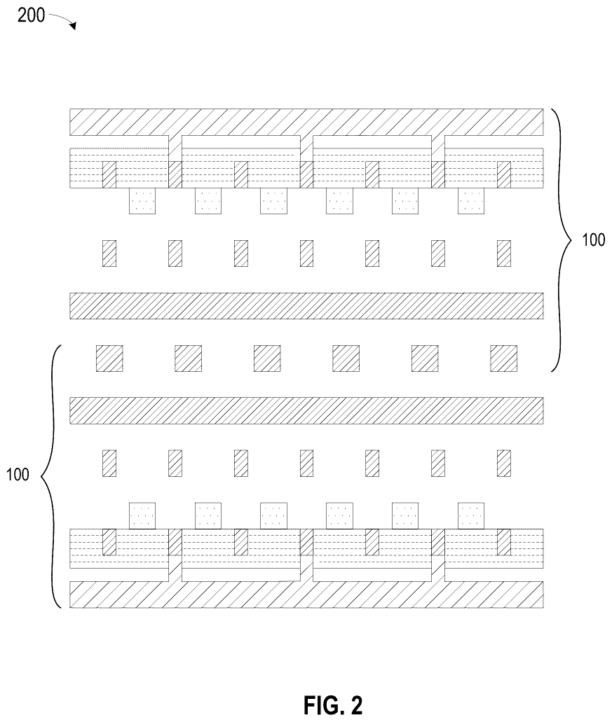

FIG. 2 shows a semiconductor substrate 200 that includes two semiconductor segments fabricated in face-to-face 3D integration (3Di), that is, a multi-tier stack of semiconductor devices with a high-density of inter-tier wiring for efficient logic-to-memory or logic-to-logic connections. These two semiconductor segments can be built separately, and each semiconductor segment can include power distribution, semiconductor devices (such as FETs) and a signal wiring structure. For example, the semiconductor substrate 200 can include two of the semiconductor segments 100 shown in FIG. 1 that are vertically stacked over each other by flipping one upside down, and each of the semiconductor segments 100 can include the power distribution (e.g., the power rails 120, the PDN 130 and the TSVs 140), the semiconductor devices (e.g., the tier of semiconductor devices 150), and the signal wiring structure (e.g., the signal wiring structure 160). In the face-to-face 3Di fabrication, these two separately built semiconductor segments 100 have to be carefully aligned to each other and bonded together face-to-face at interconnection bonding sites (e.g., bonding pads, not shown) by face-to-face bonds. Generally, one of the semiconductor segments 100 can include TSVs that lead to bumps (not shown) disposed on the top of the semiconductor segment 100, which are used to connect the semiconductor substrate 200 to its package, as described in detailed at https://spectrum.ieee.org/tech-talk/semiconductors/processors/globalfoundries-arm-close-in-on-3d-chip-integration.

High density interconnection between two or more 3D stacked semiconductor devices (e.g., the semiconductor segment 100) can ensure high performance in combination with a smaller form factor. A reliable interconnection between two stacked semiconductor devices requires a position accuracy of the interconnects in the nanometer range. Unlike overlay in an optical system, where stage and lens manipulation can be used to improve overlay, in 3Di bonding distortion of the semiconductor devices has to be controlled and corrected by dimensional shaping of the semiconductor devices. Aspects of the present disclosure provide a method to control and adapt the dimensions of a singulated and unsingulated die (e.g., the semiconductor segment 100) using lattice manipulation of the material of the semiconductor device by a focused (localized) light beam (e.g., laser).

Typical die sizes are maximum 26 mm width×33 mm length, with a typical thickness of 800 microns and thinner, even down to for instance 50 microns thickness. Bulk or carrier material of a die can be silicon, but also for instance silicon oxide or silicon nitride. The active circuits (e.g., the tier of semiconductor devices 150) can be embedded in this bulk or placed on top of this bulk or carrier die. Typical lateral size and shape deviations to be corrected are of the order of 100 nm.

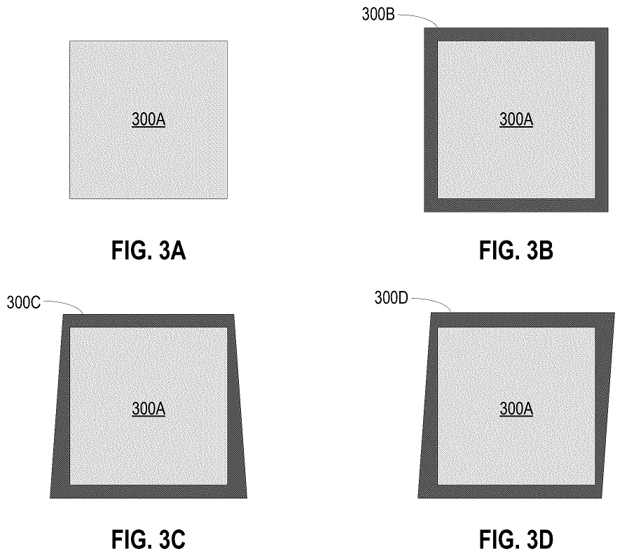

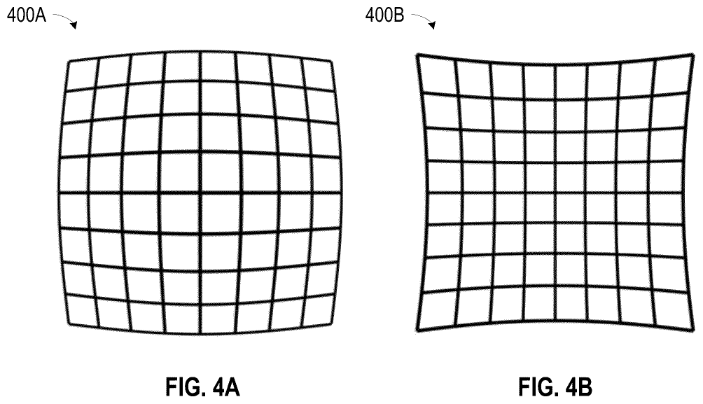

FIG. 3A shows a top view of a semiconductor substrate 300A (e.g., the semiconductor segment 100) with no distortion. As more tiers of semiconductor devices (e.g., the tier of semiconductor devices 150) and signal wiring structures (e.g., the signal wiring structure 160) are formed, the semiconductor substrate 300A may become a semiconductor device with distortion. For example, during the formation of the semiconductor devices, the semiconductor substrate 300A may become a semiconductor substrate 300B that has symmetric or scaled distortion (as shown in FIG. 3B), become a semiconductor substrate 300C that has trapezoidal distortion (as shown in FIG. 3C), or become a semiconductor substrate 300D that has shear distortion (as shown in FIG. 3D). The semiconductor substrate 300A may become a semiconductor substrate that has symmetric radial distortion. For example, the semiconductor substrate 300A may become a semiconductor substrate 400A that has barrel (negative) distortion (as shown in FIG. 4A) or become a semiconductor substrate 400B that has pincushion (positive) distortion. Aspects of the present disclosure provide a method to control and correct these distorted semiconductor substrates 300B-300D, 400A and 400B using lattice manipulation of the material of the semiconductor substrates by a focused light beam (e.g., laser).

Laser processing, e.g., femtosecond laser processing, can be used to functionalize semiconductor materials (e.g., silicon, silicon oxide and silicon nitride) in a controllable manner. The high peak intensities and characteristic of interacting with semiconductor materials more quickly than the lattice disorder and thermal diffusion time scales allow femtosecond lasers to precisely control the states of the semiconductor materials, leading to nanostructure changes and affecting material properties such as hydrophobicity, reflectivity, hardness, wear resistance, and corrosion resistance performance.

The femtosecond laser-semiconductor material interaction can involve energy transfer and thermomechanical dynamics on different time scales (or pulse duration). In the beginning of the femtosecond laser irradiation of semiconductor materials, electrons in the valence band are excited to the conduction band and thus rapidly heated to a high temperature. For example, the laser excites the nonlinear ionization of Si electrons, and photon energy is transferred to free electrons. Then, electron-lattice coupling induces a lattice temperature rise in the picosecond time scale. For example, energy is transferred from free electrons to the lattice, resulting in lattice instability, achieving thermal melting, and generating high stresses. The femtosecond laser-induced thermal stress could affect the atomic structure. Finally, thermalization of the lattice leads to rapid melting and re-solidification and changes in the interatomic forces and structural transformation of the solid semiconductor materials, and it induces lattice defects on the time scale of hundreds of picoseconds to nanoseconds.

In an embodiment, a focused light beam (e.g., laser) can implant a predetermined lattice configuration signature into a die. The die can distort according to the lattice configuration signature. The lattice configuration signature can include an amount of laser power (or energy) in the form of a focused light beam to be directed to XY positions on the die where the distortion appears. The combination of power, pulse duration, pulse number (i.e., pulse frequency) of the laser type and XY position matrix on the die results in a correction on the die distortion. For example, sufficient laser pulse energy can trigger the ultrafast melting of silicon material from solid to liquid, which arises because numerous electrons in the valence band absorbing photon energy and being excited to the conduction band, thereby destabilizing the lattice, and making the temperature in certain locations beyond the melting point of Si material. As another example, a laser irradiation area can be enlarged gradually as the pulse number increases.

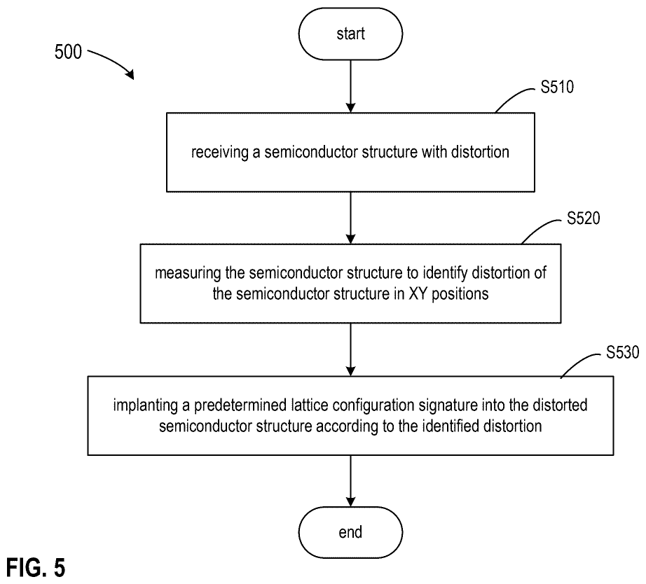

FIG. 5 is a flow chart illustrating an exemplary method 500 for controlling and adapting the dimensions of a semiconductor substrate using lattice manipulation of a semiconductor material by a focused light beam according to some embodiments of the present disclosure. For example, the semiconductor substrate can be a singulated and unsingulated die. In an embodiment, some of the steps of the exemplary method 500 shown can be performed concurrently or in a different order than shown, can be substituted by other method steps, or can be omitted. Additional method steps can also be performed as desired. In another embodiment, the exemplary method 500 can be used to correct the distorted semiconductor substrates 300B-300D, 400A and 400B. the method can start at step S510.

At step S510, a first semiconductor substrate can be received. In an embodiment, the first semiconductor substrate is with distortion. The method 500 can proceed to step S520.

At step S520, the first semiconductor substrate is measured to identify the distortion in XY positions of the first semiconductor substrate. For example, the first semiconductor substrate (e.g., the semiconductor substrates 300B-300D, 400A and 400B) can be compared with a second semiconductor substrate (e.g., the semiconductor substrate 300A) without any distortion to identify the distortion of the first semiconductor substrate in XY positions. In an embodiment, the distortion in XY positions of the first semiconductor substrate can be identified using a distortion measurement device. For example, the distortion measurement device can identify the distortion in XY positions of the first semiconductor substrate by determining alignment mark registration, overlay mark registration or reference grid registration on the first semiconductor substrate, or algorithmically based on die shape metrology. The method 500 can proceed to step S530.

At step S530, a predetermined lattice configuration signature is implanted into the distorted first semiconductor substrate. In an embodiment, a light beam (e.g., a laser) is used to implant the lattice configuration signature. For example, the lattice configuration signature can include an amount of laser power (energy) in the form of a focused light beam to be directed to XY positions on the die where the distortion appears, leading to correcting the die distortion. In an embodiment, the power, pulse duration and pulse number of the laser light beam can be adjusted according to the identified die distortion in XY positions.

For example, regarding the semiconductor substrate 300B with the symmetric or scale distortion, the semiconductor substrate 300C with the trapezoidal distortion and the semiconductor substrate 300D with the shear distortion, the power, pulse duration and pulse number can be adjusted by the laser type and function and tuned to the material, lattice and interfaces below of the semiconductor structures 300B, 300C and 300D and directed to XY positions on the semiconductor structures 300B, 300C and 300D where the distortion appears (e.g., a shaded region, as shown in FIGS. 3B-3D), in order to, for example, trigger ultrafast melting of silicon material from solid to liquid, thereby destabilizing the lattice, and making the temperature in the XY positions beyond the melting point of silicon material, leading to correcting the die distortion.

Regarding the semiconductor substrate 400A with the barrel (negative) distortion and the semiconductor substrate 400B with the pincushion (positive) distortion, the power, pulse duration and pulse number of the laser light beam can be adjusted by the laser type and function and tuned to the material, lattice and interfaces below of the semiconductor structures 400A and 400B and directed to XY positions on the semiconductor structures 400A and 400B where the distortion appears (e.g., the edge of the barrel and the pincushion), in order to, for example, trigger ultrafast melting of silicon material from solid to liquid, thereby destabilizing the lattice, and making the temperature in the XY positions beyond the melting point of silicon material, leading to correcting the die distortion.

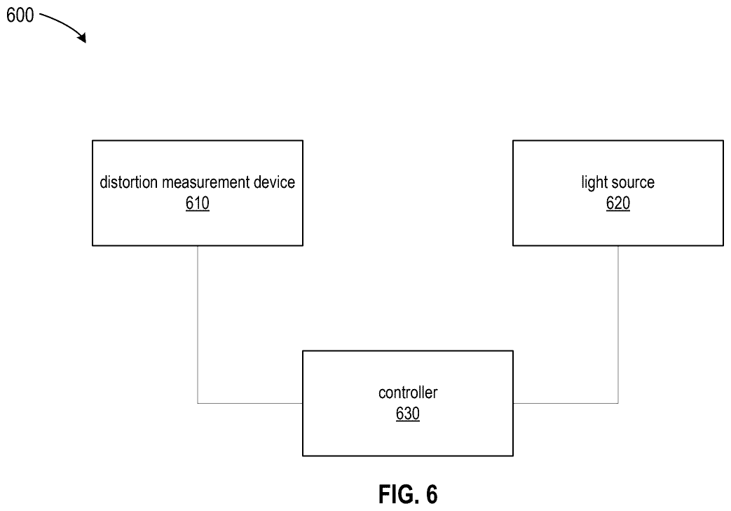

FIG. 6 is a functional block diagram of an exemplary apparatus 600 for correcting distortion of a semiconductor structure according to some embodiments of the present disclosure. The apparatus 600 can be used to implement the method 500. The apparatus 600 can include a distortion measurement device 610 that is configured to measure the semiconductor substrate to identify the distortion in a plurality of positions (e.g., XY positions) on the semiconductor substrate. The apparatus 600 can further include a light source 620 that is configured to implant a predetermined lattice configuration signature into the semiconductor substrate to distort the semiconductor substrate. The apparatus 600 can further include a controller 630 that is coupled to the distortion measurement device 610 and the light source 620. In an embodiment, the controller 630 can be configured to control the light source 620 to implant the predetermined lattice configuration into the semiconductor substrate according to the identified distortion in the positions on the semiconductor substrate.

In an embodiment, the light source 620 can be configured to implant into the semiconductor substrate the lattice configuration signature by focusing a light beam with an amount of energy in the positions on the semiconductor substrate. For example, the light source 620 can be a laser light source that is configured to implant into the semiconductor substrate the lattice configuration signature by focusing a laser light beam with an amount of laser energy in the positions on the semiconductor substrate. In some embodiments, the laser light beam can have power, pulse duration and pulse number that are adjusted according to the identified distortion in the positions. In various embodiments, the laser light beam can be tuned to a material and a lattice of the semiconductor substrate and an interface below the semiconductor substrate.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with some embodiments of the present disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the present disclosure are not intended to be limiting. Rather, any limitations to embodiments of the present disclosure are presented in the following claims.

What is claimed is:

1. A method for correcting distortion of a semiconductor substrate, comprising:
receiving a semiconductor substrate with distortion;
measuring the semiconductor substrate to identify the distortion in a plurality of positions on the semiconductor substrate; and
implanting into the semiconductor substrate a lattice configuration signature according to the identified distortion in the positions on the semiconductor substrate such that the identified distortion of the semiconductor substrate is corrected.

2. The method of claim 1, wherein implanting into the semiconductor substrate the lattice configuration signature includes focusing a light beam with an amount of energy in the positions on the semiconductor substrate.

3. The method of claim 2, wherein focusing the light beam with the amount of energy includes focusing a laser light beam with an amount of laser energy.

4. The method of claim 3, wherein the laser light beam has power that is adjusted according to the identified distortion in the positions.

5. The method of claim 3, wherein the laser light beam has a pulse duration that is adjusted according to the identified distortion in the positions.

6. The method of claim 3, wherein the laser light beam has a pulse number that is adjusted according to the identified distortion in the positions.

7. The method of claim 3, wherein the laser light beam is tuned to a material of the semiconductor substrate.

8. The method of claim 3, wherein the laser light beam is tuned to a lattice of the semiconductor substrate.

9. The method of claim 4, wherein the laser light beam is tuned to an interface below the semiconductor substrate.

10. The method of claim 1, wherein the positions include XY positions.

11. The method of claim 10, wherein the distortion in the XY positions is identified by determining alignment mark registration, overlay mark registration and/or reference grid registration on the semiconductor substrate.

12. An apparatus for correcting distortion of a semiconductor substrate, comprising:
a distortion measurement device configured to measure the semiconductor substrate to identify the distortion in a plurality of positions on the semiconductor substrate;
a light source configured to implant a lattice configuration signature into the semiconductor substrate to distort the semiconductor substrate; and
a controller coupled to the distortion measurement device and the light source, the controller configured to control the light source to implant the lattice configuration signature into the semiconductor substrate according to the identified distortion in the positions on the semiconductor substrate.

13. The apparatus of claim 12, wherein the light source is configured to implant into the semiconductor substrate the lattice configuration signature by focusing a light beam with an amount of energy in the positions on the semiconductor substrate.

14. The apparatus of claim 13, wherein the light source is a laser light source that is configured to implant into the semiconductor substrate the lattice configuration signature by focusing a laser light beam with an amount of laser energy in the positions on the semiconductor substrate.

15. The apparatus of claim 14, wherein the laser light beam has power that is adjusted according to the identified distortion in the positions.

16. The apparatus of claim 14, wherein the laser light beam has a pulse duration that is adjusted according to the identified distortion in the positions.

17. The apparatus of claim 14, wherein the laser light beam has a pulse number that is adjusted according to the identified distortion in the positions.

18. The apparatus of claim 14, wherein the laser light beam is tuned to a material of the semiconductor substrate.

19. The apparatus of claim 14, wherein the laser light beam is tuned to a lattice of the semiconductor substrate.

20. The apparatus of claim 12, wherein the positions include XY positions.
